(19) United States
(12) Patent Application Publication
(10) Pub. No.: US 2016/0204078 A1
(43) Pub. Date: Jul. 14, 2016

(54) BONDING PROCESS USING TEMPERATURE CONTROLLED CURVATURE CHANGE

(71) Applicant: International Business Machines Corporation, Armonk, NY (US)

(72) Inventors: Stephen W. Bedell, Wappingers Falls, NY (US); Cheng-Wei Cheng, White Plains, NY (US); Keith E. Fogel, Hopewell Junction, NY (US); Ning Li, White Plains, NY (US); Devendra K. Sadana, Pleasantville, NY (US)

(21) Appl. No.: 14/596,861

(22) Filed: Jan. 14, 2015

(51) Int. Cl. H01L 23/00; B32B 37/14; B32B 38/10

(52) U.S. Cl. CPC H01L 24/83; B32B 38/10; B32B 37/14; H01L 2224/83002; H01L 2224/83047; H01L 2224/83888; H01L 2224/83095; H01L 2924/01028; H01L 2924/201

(57) ABSTRACT

A first substrate including a radius of curvature and a stressor layer is first provided. An outermost bowed, e.g., curved, surface of the first substrate is then brought into intimate contact with a surface of a second substrate. Bonding of the entirety of the first substrate to the second substrate is then achieved by reducing the radius of curvature of the first substrate by controlling the temperature at which bonding occurs.

### BACKGROUND

The present application relates to semiconductor manufacturing, and more particularly to a method in which a first substrate having a radius of curvature and containing a stressor layer is bonded to a surface of a second substrate by relaxing the curvature of the first substrate by modulating the temperature at which the bonding is performed.

Devices such as, for example, photovoltaic and electro-optical, that can be produced in thin-film form have three clear advantages over their bulk counterparts. First, by virtue of less material used, thin-film devices ameliorate the materials cost associated with device production. Second, low device weight is a definite advantage that motivates industrial-level effort for a wide range of thin-film applications. Third, if dimensions are small enough, devices can exhibit mechanical flexibility in their thin-film form. Furthermore, if a device layer is removed from a substrate that can be reused, additional fabrication cost reduction can be achieved.

Efforts to (i) create thin-film substrates from bulk materials (i.e., semiconductors) and (ii) form thin-film device layers by removing device layers from the underlying bulk substrates on which they were formed are ongoing. The recent development, see, for example, U.S. Patent Application Publication No. 2010/0311250 A1 to Bedell et al., of a novel layer transfer method referred to as ‘controlled spalling technology’ has permitted the fabrication of low-cost, thin-film, high quality substrates by removing a surface layer from a base substrate. The thin-film substrate layers that can be removed by this controlled spalling technology can be used to 1) increase the cost per Watt value of conventional photovoltaic technology or 2) permit fabrication of novel, high-efficiency photovoltaic, electronic and opto-electronic materials that are flexible and can be used to produce new products.

In order to handle and process the thin-film substrate layers (as thin as a few microns) that are produced by spalling, it is essential to mount them properly on wafer carriers (i.e., substrates) such as, for example, rigid substrates or flexible substrates. Although various wafer bonding processes exist, a specific process needs to be developed for spalled wafers because 1) the spalled thin-film substrate layers are curved films that include a spalled material portion of an original base substrate and a stress inducing layer (referred to as a stressor layer), instead of a single flat thin film, and 2) the stress in the spalled thin-film substrate layer needs to be released gradually and uniformly to minimize the possibility of film cracking. Also, any bonding process that is developed needs to be low cost so that can be used in fabricating high-efficiency photovoltaic, electronic and opto-electronic materials.

### SUMMARY

A first substrate including a radius of curvature and a stressor layer is first provided. An outermost bowed, e.g., curved, surface of the first substrate is then brought into intimate contact with a portion of a surface (flat relative to the curved surface of the first substrate) of a second substrate. Bonding of the entirety of the first substrate to the second substrate is then achieved by reducing the radius of curvature of the first substrate by controlling the temperature at which bonding occurs.

In one aspect of the present application, a method is provided that includes providing a first substrate having a radius of curvature and containing a stressor layer. An outermost bowed surface of the first substrate is then brought into contact with a portion of a surface of a second substrate. Next, the first substrate is bonded to an entirety of the surface of the second surface. In accordance with the present application, bonding is performed at a temperature that removes the radius of curvature of the first substrate. Following bonding, and in some embodiments of the present application, the stressor layer can be removed from the first substrate.

### BRIEF DESCRIPTION OF SEVERAL VIEWS OF THE DRAWINGS

FIG. 1 is a cross sectional view of an exemplary structure including a base substrate that can be employed in one embodiment of the present application.

FIG. 2 is a cross sectional view of the exemplary structure of FIG. 1 after forming an edge exclusion material at the edges of the base substrate in accordance with another embodiment of the present application.

FIG. 3 is a cross sectional view of the exemplary structure of FIG. 2 after forming a metal-containing adhesion layer on exposed surfaces of the edge exclusion material and the base substrate in accordance with an embodiment of the present application.

FIG. 4 is a cross sectional view of the exemplary structure of FIG. 3 after forming a stressor layer on a surface of the metal-containing adhesion layer in accordance with an embodiment of the present application.

FIG. 5 is a cross sectional view of the exemplary structure of FIG. 4 after forming a handle substrate on a surface of the stressor layer in accordance with an embodiment of the present application.

FIG. 6 is a cross sectional view of the exemplary structure of FIG. 5 after performing a spalling process in accordance with an embodiment of the present application.

FIG. 7 is a cross sectional view of the exemplary structure of FIG. 6 after contacting an outermost bowed surface of a spalled material portion of the base substrate to a substrate in accordance with an embodiment of the present application.

FIG. 8 is a cross sectional view of the exemplary structure of FIG. 7 after performing the bonding process of the present application.

FIG. 9 is a cross sectional view of the exemplary structure of FIG. 8 after removing various material layers from the bonded structure.

FIG. 10 is a cross sectional view of another exemplary structure including a base substrate and a stressor layer in accordance with another embodiment of the present application.

FIG. 11 is a cross sectional view of the exemplary structure of FIG. 10 after contacting an outermost bowed surface of the base substrate to a substrate.

FIG. 12 is a cross sectional view of the exemplary structure of FIG. 11 after performing the bonding process of the present application and removing the stressor layer from the bonded structure.

### DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

In the present application, a method of bonding a first substrate to a second substrate is provided. The method includes providing a first substrate including a radius of curvature. The first substrate may include a spalled material portion of a base substrate or a non-spalled base substrate. A stressor layer (i.e., a stress inducing layer) is located atop a surface of the first substrate. An outermost bowed surface of the first substrate is then brought into intimate contact with a surface of a second substrate. Bonding of the entirety of the first substrate to the second substrate is then achieved by reducing the radius of curvature of the first substrate by controlling the temperature at which bonding occurs.

One advantage of the method of the present application is that is releases the stress uniformly and in a controlled manner to ensure formation of a bubble free uniform bonding interface between the first and second substrates. By “bubble free uniform bonding interface” it is meant that the entire surface of one substrate is in contiguous contact with an entire surface of another substrate without any voids, trapped gases or liquids being present between the two substrates. In a typical bonding process, gases and liquids may get trapped at the interface forming a bubble after bonding. Another advantage of the method of the present application is that is does not require any special wafer bending fixture. A further advantage of the method of the present application is that it is low cost and can be applied to a spalled material portion of a base substrate or a non-spalled base substrate.

In one embodiment of the present application, the bonding process of the present application can be used to bond a thin film substrate formed from a controlled spalling process to a substrate. As used herein, a controlled spalling process is a layer transfer technology that uses mechanically guided fracture to separate a surface layer from a base substrate. The spalling process works by first forming a stressor layer, e.g., a Ni layer, atop a surface of a base substrate. A handle substrate can then be attached to the surface of the stressor layer. By using the handle layer to initiate and guide the fracture front that forms below the upper surface of the base substrate, a simple and robust layer transfer process can be achieved.

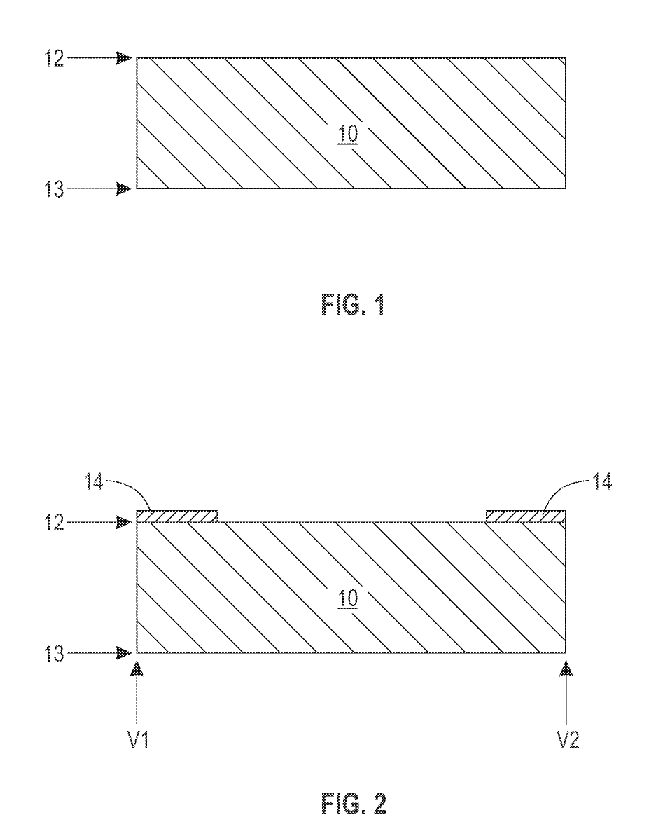

Referring first to FIG. 1, there is illustrated an exemplary structure including a base substrate 10 that can be employed in accordance with an embodiment of the present application. The base substrate 10 includes a first surface (i.e., topmost surface) 12 and a second surface (i.e., bottommost surface) 13 that is opposite the first surface 12.

The base substrate 10 that can be employed in the present application may comprise a semiconductor material, a glass, a ceramic or any another material or combination of materials whose fracture toughness is less than that of the stressor layer to be subsequently formed. Fracture toughness is a property which describes the ability of a material containing a crack to resist fracture. Fracture toughness is denoted K_{Ic}. The subscript Ic denotes mode I crack opening under a normal tensile stress perpendicular to the crack, and c signifies that it is a critical value. Mode I fracture toughness is typically the most important value because spalling mode fracture usually occurs at a location in the substrate where mode II stress (shearing) is zero. Fracture toughness is a quantitative way of expressing a material's resistance to brittle fracture when a crack is present.

When the base substrate 10 comprises a semiconductor material, the semiconductor material may include, but is not limited to, Si, Ge, SiGe, SiGeC, SiC, Ge alloys, compounds semiconductor such as, for example III-V compound semiconductors or II-VI compound semiconductor. In some embodiments, the base substrate 10 can be a III-V compound semiconductor such as, for example, GaSb, GaP, GaN, GaAs, InAs, InP, InAsP and AN. In some embodiments, the base substrate 10 is a bulk semiconductor material. In other embodiments, the base substrate 10 may comprise a layered semiconductor material such as, for example, a semiconductor-on-insulator or a semiconductor on a polymeric substrate. Illustrated examples of semiconductor-on-insulator substrates that can be employed as base substrate 10 include silicon-on-insulators and silicon-germanium-on-insulators. In some embodiments, base substrate 10 comprises a multilayered stack of semiconductor materials. An illustrated example of such a base substrate is a multilayered stack of from bottom to top, a layer of germanium, and a layer of gallium arsenide. When the base substrate 10 comprises a semiconductor material, the semiconductor material can be doped, undoped or contain doped regions and undoped regions.

In one embodiment, the semiconductor material that can be employed as the base substrate 10 can be single crystalline (i.e., a material in which the crystal lattice of the entire sample is continuous and unbroken to the edges of the sample, with no grain boundaries). In another embodiment, the semiconductor material that can be employed as the base substrate 10 can be polycrystalline (i.e., a material that is composed of many crystallites of varying size and orientation; the variation in direction can be random (called random texture) or directed, possibly due to growth and processing conditions). In yet another embodiment of the present application, the semiconductor material that can be employed as the base substrate 10 can be amorphous (i.e., a non-crystalline material that lacks the long-range order characteristic of a crystal). Typically, the semiconductor material that can be employed as the base substrate 10 is a single crystalline material.

When the base substrate 10 comprises a glass, the glass can be a SiO₂-based glass which may be undoped or doped with an appropriate dopant. Examples of SiO₂-based glasses that can be employed as the base substrate 10 include undoped silicate glass, borosilicate glass, phosphosilicate glass, fluorosilicate glass, and borophosphosilicate glass.

When the base substrate 10 comprises a ceramic, the ceramic can be any inorganic, non-metallic solid such as, for example, an oxide including, but not limited to, alumina, beryllia, ceria and zirconia, a non-oxide including, but not limited to, a carbide, a boride, a nitride or a silicide; or composites that include combinations of oxides and non-oxides.

In some embodiments of the present application, one or more devices (not shown) including, but not limited to, transistors, capacitors, diodes, BiCMOS, resistors, etc. can be processed on and/or within the base substrate 10 utilizing techniques well known to those skilled in the art. An upper region (or portion) of the base substrate 10 which may include the one or more devices can be removed utilizing a mechanical layer transfer process known as spalling. In some embodiments of the present application, the upper region of the base substrate 10 may also include one or more III-V compound semiconductor layers which can be used as a photovoltaic device.

In some embodiments of the present application, the first surface 12 of the base substrate 10 can be cleaned prior to further processing to remove surface oxides and/or other contaminants therefrom. In one embodiment of the present application, the first surface 12 of the base substrate 10 is cleaned by applying to the first surface 12 of the base substrate 10 a solvent such as, for example, acetone and isopropanol, which is capable of removing contaminates and/or surface oxides from the first surface 12 of the base substrate 10.

In some embodiments of the present application, the first surface 12 of the base substrate 10 can be made hydrophobic by oxide removal prior to use by dipping the first surface 12 of the base substrate 10 into hydrofluoric acid. A hydrophobic, or non-oxide, surface provides improved adhesion between the cleaned surface and certain stressor layers to be deposited.

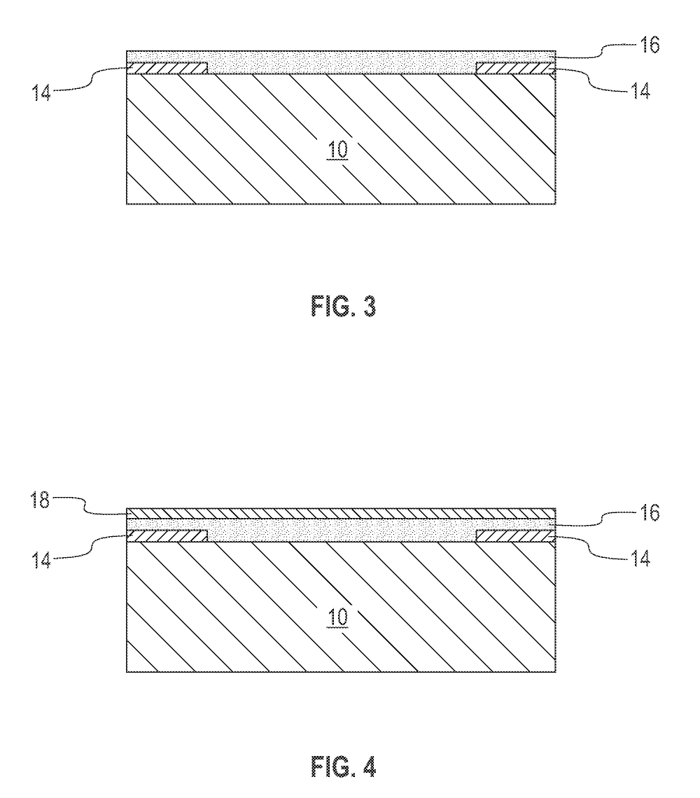

Referring now to FIG. 2, there is illustrated the exemplary structure shown in FIG. 1 after forming an edge exclusion material 14 on the first surface 12 and at the vertical edges V1, V2 of the base substrate 10. In some embodiments of the present application, the edge exclusion material can be omitted and the process of the present application proceeds as shown in FIG. 3. In embodiments in which an edge exclusion material 14 is present, the edge exclusion material 14 has one edge that is vertically coincident with vertical edge V1,V2 of the base substrate 10, while another edge of the edge exclusion material 14 is located inward from edge V1,V2 and on the first surface 12 of the base substrate 10.

In one embodiment of the present application, the edge exclusion material 14 can be an adhesion demoter. By “adhesion demoter” it is meant any material that reduces the ability of a subsequently formed optional metal-containing adhesion layer or stressor layer to adhere, i.e., stick, to the first surface 12 of the base substrate 10. The adhesion demoters that can be employed in the present application as the edge exclusion material 14 include, but are not limited to, photoresist materials, polymers, hydrocarbon materials, inks, powders, pastes or non-adherent metals. In one embodiment, the adhesion demoter that can be employed in the present application as the edge exclusion material 14 is an ink.

The photoresist materials that can be employed as the adhesion demoter include any well known positive-tone materials and/or negative-tone materials. The polymers that can be employed as the adhesion demoter include, but are not limited to, natural polymers such as rubbers, shellac, cellulose, synthetic polymers such as nylon, polyethylene and polypropylene, deposited or applied in the form of tape or film. The hydrocarbon materials that can be employed as the adhesion demoter include, but are not limited to, saturated hydrocarbons (i.e., alkanes), unsaturated hydrocarbons (i.e., alkenes or alkynes), cycloalkanes, and/or aromatic hydrocarbons (i.e., arenes). Inks that can be employed as the adhesion demoter include, but are not limited to, alcohol or water-based inks commonly found in commercial permanent markers or inks used in bubble-jet printing technology. Non-adherent metals that can be employed as the adhesion demoter include, but are not limited to, Au, Ag, solders or low-melting point alloys. Pastes that can be employed as the adhesion demoter include, but are not limited to, metal based pastes, partially-cured epoxies, vacuum grease or similar materials.

The adhesion demoters that can be employed in the present application as the edge exclusion material 14 can be formed onto the first surface 12 of the base substrate 10 near edges V1, V2 utilizing techniques that are well known in the art. For example, the adhesion demoters that can be employed in the present application as the edge exclusion material 14 can be formed by chemical vapor deposition, plasma enhanced chemical vapor deposition, atomic layer deposition, spin-coating, brushing, spray coating, screen-printing, bubble-jet printing, or fabric-tip application. In some embodiments in which inks are employed as the adhesion demoters, the ink can be applied from a pen or marker containing the same. In one embodiment, the edge exclusion material 14 has a width, which is determined from one sidewall edge to another sidewall edge, of from 0.01 mm to 10 mm. In another embodiment, the edge exclusion material 14 has a width of from 0.1 mm to 5 mm. It is observed that the portion of the base substrate 10 that is located directly beneath the edge exclusion material 14 defines an edge exclusion region whose presence minimizes edge related breakage during a subsequent spalling process. The term “edge exclusion region” is used throughout the present application to denote an area atop the base substrate 10 in which a subsequently formed stressor layer is either not present or if, present, the stressor layer does not significantly adhere to the first surface 12 of the base substrate 10.

Referring now to FIG. 3, there is illustrated the exemplary structure of FIG. 2 after forming an optional metal-containing adhesion layer 16 on exposed surfaces of the edge exclusion material 14 and on exposed portions of the first surface 12 of the base substrate 10. In some embodiments, and when no edge exclusion material 14 is present, the optional metal-containing adhesion layer 16 can be formed directly on the entirety of the first surface 12 of base substrate 10.

The optional metal-containing adhesion layer 16 is employed in embodiments in which the stressor layer to be subsequently formed has poor adhesion to first surface 12 of the base substrate 10. Typically, the metal-containing adhesion layer 16 is employed when a stressor layer comprised of a metal is employed. In some embodiments, an optional plating seed layer (not shown) can be formed directly atop the first surface 12 of the base substrate 10. The optional plating seed layer can be used together with the metal-containing adhesion layer 16 or in lieu thereof. When the optional plating seed layer is employed in conjunction with the edge exclusion material 14, the edge exclusion material 14 is applied to the first surface 12 of the base substrate 10 prior to deposition of the plating seed layer.

The optional metal-containing adhesion layer 16 that can be employed in the present application includes any metal adhesion material such as, but not limited to, Ti/W, Ti, Cr, Ni or any combination thereof. The optional metal-containing adhesion layer 16 may comprise a single layer or it may include a multilayered structure comprising at least two layers of different metal adhesion materials.

When present, the optional metal-containing adhesion layer 16 can be formed at a temperature from 15° C. to 40° C., i.e., 288K to 313K, or above. In one embodiment, the optional metal-containing adhesion layer 16 can be formed at a temperature which is from 20° C. (293K) to 180° C. (353K). In another embodiment, the optional metal-containing adhesion layer 16 can be formed at a temperature which is from 20° C. (293K) to 60° C. (333K).

The metal-containing adhesion layer 16, which may be optionally employed, can be formed utilizing deposition techniques that are well known to those skilled in the art. For example, the optional metal-containing adhesion layer 16 can be formed by sputtering, chemical vapor deposition, plasma enhanced chemical vapor deposition, chemical solution deposition, physical vapor deposition, or plating. When sputter deposition is employed, the sputter deposition process may further include an in-situ sputter clean process before the deposition.

When employed, the optional metal-containing adhesion layer 16 typically has a thickness from 5 nm to 300 nm, with a thickness from 100 nm to 150 nm being more typical. Other thicknesses for the optional metal-containing adhesion layer 16 that are below and/or above the aforementioned thickness ranges can also be employed in the present application.

The optional plating seed layer (not shown) is typically employed in embodiments in which the stressor layer to be subsequently formed is a metal and plating is used to form the metal-containing stressor layer. The optional plating seed layer is employed to selectively promote subsequent plating of a pre-selected metal-containing stressor layer. The optional plating seed layer may comprise, for example, a single layer of Ni or a layered structure of two or more metals such as Ti/Ni, Ti/Ag, Ti/Au, Cr/Ni, Cr/Ag, Cr/Au, Al(bottom)/Ti/Ni(top), etc. The thickness of the optional plating seed layer may vary depending on the material or materials of the optional plating seed layer as well as the technique used in forming the same. Typically, the optional plating seed layer has a thickness from 2 nm to 1 micron. The optional plating seed layer can be formed by a conventional deposition process including, for example, chemical vapor deposition (CVD), plasma-enhanced chemical vapor deposition (PECVD), atomic layer deposition (ALD), or physical vapor deposition (PVD) techniques that may include evaporation and/or sputtering.

In accordance with the present application, the optional metal-containing adhesion layer 16 and/or the optional plating seed layer is (are) formed at a temperature which does not effectuate spontaneous spalling to occur within the base substrate 10.

Referring now to FIG. 4, there is illustrated the exemplary structure of FIG. 3 after forming a stressor layer 18 on an upper surface of the optional metal-containing adhesion layer 16. In some embodiments in which the optional metal-containing adhesion layer 16 is not present, the stressor layer 18 can be formed directly on the first surface 12 of base substrate 10; this particular embodiment is not shown in the drawings, but can readily be deduced from the drawings illustrated in the present application. In other embodiments in which an optional plating seed layer is employed, the stressor layer 18 can be formed directly on the upper surface of the optional plating seed layer; this particular embodiment is also not shown in the drawings, but can readily be deduced from the drawings illustrated in the present application.

The stressor layer 18 that can be employed in the present application includes any material that is under tensile stress on base substrate 10 after deposition. The stressor layer 18 can also be referred to a stress inducing layer. In accordance with the present application, the stressor layer 18 has a critical thickness and a stress value that cause spalling mode fracture to occur within the base substrate 10. In particular, the stressor layer 18 has a critical thickness in which spalling is initiated below the first surface 12 of base substrate 10 and somewhere within the base substrate 10. By ‘critical’, it is meant that for a given stressor material and base substrate material combination, a thickness value and a stressor value for the stressor layer is chosen that render spalling mode fracture possible (can produce a K_{I} value greater than the K_{IC} of the substrate). The stress value can be adjusted by tuning the deposition conditions of the stressor layer 18. For example, in the case of sputter deposition of stressor layer 18, the gas pressure can be used to tune the stress value as described in Thorton and Hoffman, J. Vac. Sci. Technol., 14 (1977) p. 164.

The thickness of the stressor layer 18 is chosen to provide the desired fracture depth somewhere within the base substrate 10. For example, if the stressor layer 18 is chosen to be Ni, then fracture will occur at a depth below the stressor layer 18 roughly 2 to 3 times the Ni thickness. The stress value for the stressor layer 18 is then chosen to satisfy the critical condition for spalling mode fracture. This can be estimated by inverting the empirical equation given by t*=[(2.5×10⁶)(K_{IC}^{3/2})]/σ², where t* is the critical stressor layer thickness (in microns), K_{IC} is the fracture toughness (in units of MPa·m^{1/2}) of the base substrate 10 and σ is the stress value of the stressor layer (in MPa or megapascals). The above expression is a guide, in practice, spalling can occur at stress or thickness values up to 20% less than that predicted by the above expression.

Illustrative examples of such materials that are under tensile stress when applied atop the base substrate 10 and thus can be employed as the stressor layer 18 include, but are not limited to, a metal, a polymer, such as a spall inducing tape layer, or any combination thereof. The stressor layer 18 may comprise a single stressor layer, or a multilayered stressor structure including at least two layers of different stressor material can be employed.

In one embodiment, the stressor layer 18 is a metal, and the metal is formed on an upper surface of the optional metal-containing adhesion layer 16. In another embodiment, the stressor layer 18 is a spall inducing tape, and the spall inducing tape is applied directly to the first surface 12 of the base substrate 10. In another embodiment, for example, the stressor layer 18 may comprise a two-part stressor layer including a lower part and an upper part. The upper part of the two-part stressor layer can be comprised of a spall inducing tape layer.

When a metal is employed as the stressor layer 18, the metal can include, for example, Ni, Cr, Fe, Mo, Ti or W. Alloys of these metals can also be employed. In one embodiment, the stressor layer 18 includes at least one layer consisting of Ni.

When a polymer is employed as the stressor layer 18, the polymer is a large macromolecule composed of repeating structural units. These subunits are typically connected by covalent chemical bonds. Illustrative examples of polymers that can be employed as the stressor layer 18 include, but are not limited to, polyimides polyesters, polyolefins, polyacrylates, polyurethane, polyvinyl acetate, or polyvinyl chloride.

When a spall inducing non-metallic layer (i.e. polymeric materials such as a tape) is employed as the stressor layer 18, the spall inducing layer includes any pressure sensitive tape that is flexible, soft, and stress free at a first temperature used to form the tape, yet strong, ductile and tensile at a second temperature used during removal, i.e., spalling of an upper portion of the base substrate 10. By “pressure sensitive tape,” it is meant an adhesive tape that will stick with application of pressure, without the need for solvent, heat, or water for activation. Tensile stress in the tape at the second temperature is primarily due to thermal expansion mismatch between the base substrate 10 (with a lower thermal coefficient of expansion) and the tape (with a higher thermal expansion coefficient).

Typically, the pressure sensitive tape that is employed in the present application as stressor layer 18 includes at least an adhesive layer and a base layer. Materials for the adhesive layer and the base layer of the pressure sensitive tape include polymeric materials such as, for example, acrylics, polyesters, olefins, and vinyls, with or without suitable plasticizers. Plasticizers are additives that can increase the plasticity of the polymeric material to which they are added.

In one embodiment, the stressor layer 18 employed in the present application is formed at room temperature (15° C.-40° C., i.e., 288K-313K). In another embodiment, when a tape layer is employed, the tape layer can be formed at a temperature from 15° C. (288K) to 60° C. (333K).

When the stressor layer 18 is a metal or polymer, the stressor layer 18 can be formed utilizing deposition techniques that are well known to those skilled in the art including, for example, dip coating, spin-coating, brush coating, sputtering, chemical vapor deposition, plasma enhanced chemical vapor deposition, chemical solution deposition, physical vapor deposition, or plating.

When the stressor layer 18 is a spall inducing tape layer, the tape layer can be applied by hand or by mechanical means to the structure. The spall inducing tape can be formed utilizing techniques well known in the art or they can be commercially purchased from any well known adhesive tape manufacturer. Some examples of spall inducing tapes that can be used in the present application as stressor layer 18 include, for example, Nitto Denko 3193MS thermal release tape, Kapton KPT-1, and Diversified Biotech's CLEAR-170 (acrylic adhesive, vinyl base).

In one embodiment, a two-part stressor layer can be formed on the first surface 12 of base substrate 10, wherein a lower part of the two-part stressor layer is formed at a first temperature which is at room temperature or slight above (e.g., from 15° C. (288K) to 60° C. (333K)), wherein an upper part of the two-part stressor layer comprises a spall inducing tape layer at an auxiliary temperature which is at room temperature.

If the stressor layer 18 is of a metallic nature, it typically has a thickness of from 1 μm to 50 μm, with a thickness of from 4 μm to 7 μm being more typical. Other thicknesses for the stressor layer 18 that are below and/or above the aforementioned thickness ranges can also be employed in the present application.

If the stressor layer 18 is of a polymeric nature, it typically has a thickness of from 10 μm to 200 μm, with a thickness of from 50 μm to 100 μm being more typical. Other thicknesses for the stressor layer 18 that are below and/or above the aforementioned thickness ranges can also be employed in the present application.

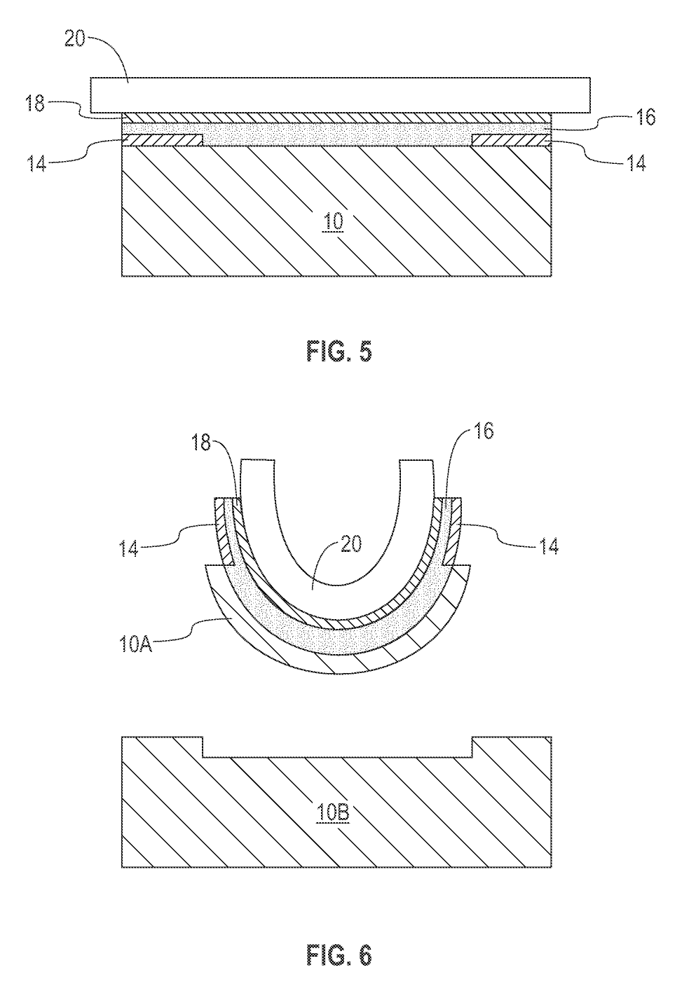

Referring now to FIG. 5, there is illustrated the exemplary structure of FIG. 4 after forming a handle substrate 20 atop the stressor layer 18. In some embodiments of the present application, the handle substrate 20 can be omitted. When present, the handle substrate 20 can include any flexible material which has a minimum radius of curvature of less than 30 cm. Illustrative examples of flexible materials that can be employed as the handle substrate 20 include a metal foil or a polyimide foil.

The handle substrate 20 can be used to provide better fracture control and more versatility in handling the spalled portion of the base substrate 10. Moreover, the handle substrate 20 can be used to guide the crack propagation during a subsequently performed spalling process. The handle substrate 20 of the present application is typically, but not necessarily, formed at a first temperature which is at room temperature (15° C. (288K)-40° C. (313K)).

The handle substrate 20 can be formed utilizing deposition techniques that are well known to those skilled in the art including, for example, mechanical pressure, dip coating, spin-coating, brush coating, sputtering, chemical vapor deposition, plasma enhanced chemical vapor deposition, chemical solution deposition, physical vapor deposition, or plating.

The handle substrate 20 typical has a thickness of from 5 μm to 500 μm, with a thickness of from 10 μm to 150 μm being more typical. Other thicknesses for the handle substrate 20 that are below and/or above the aforementioned thickness ranges can also be employed in the present application. As shown, the handle substrate 20 typically has a length that extends beyond the length of the base substrate 10.

Referring now to FIG. 6, there is illustrated the exemplary structure of FIG. 5 after removing an upper portion of the base substrate 10 by spalling. In one embodiment of the present application, the spalling process includes pulling or peeling the handle substrate 20 to remove a spalled structure that includes at least the stressor layer 18 and an upper portion of the base substrate 10. The upper portion of the base substrate 10 that is removed by spalling from the original base substrate 10 may be referred herein as a spalled material portion 10A. The remaining portion of the original base substrate 10 may be referred to herein as remaining base substrate portion 10B.

The spalling process includes crack formation and propagation within the base substrate 10. The spalling process is initiated at substantially room temperature (i.e., 15° C. to 40° C.). In other embodiments, spalling can be performed at a temperature from 100° C. and below. In some embodiments of the present application, spalling can be initiated by lowering the temperature at a fixed continuous rate. By “fixed continuous rate” it is mean, for example, 20° C. per second utilizing an electronically controlled cooling table or chamber. This method of cooling allows one to reach a pre-specified temperature at which user-defined spalling initiation can induce a pre-determined spalling depth that may be different than that dictated by mere structural parameters (i.e., stressor layer stress and thickness, and fracture toughness of substrate).

After spalling, a curved structure is provided that includes at least stressor layer 18, and spalled material portion 10A. In some embodiments, the curved structure may also include the handle substrate 20, the plating seed layer, the metal-containing adhesion layer 16 and the edge exclusion material 14. The thickness of the spalled material portion 10A that is removed from the base substrate 10 varies depending on the material of the stressor layer 18 and the material of the base substrate 10 itself. In one embodiment, the spalled material portion 10A that is removed from the base substrate 10 has a thickness of less than 100 microns. In another embodiment, the spalled material portion 10A that is removed from the base substrate 10 has a thickness of less than 50 microns. The radius of curvature of the structure including at least the stressor layer 18 and the material portion 10A is from 1 mm to 100 cm.

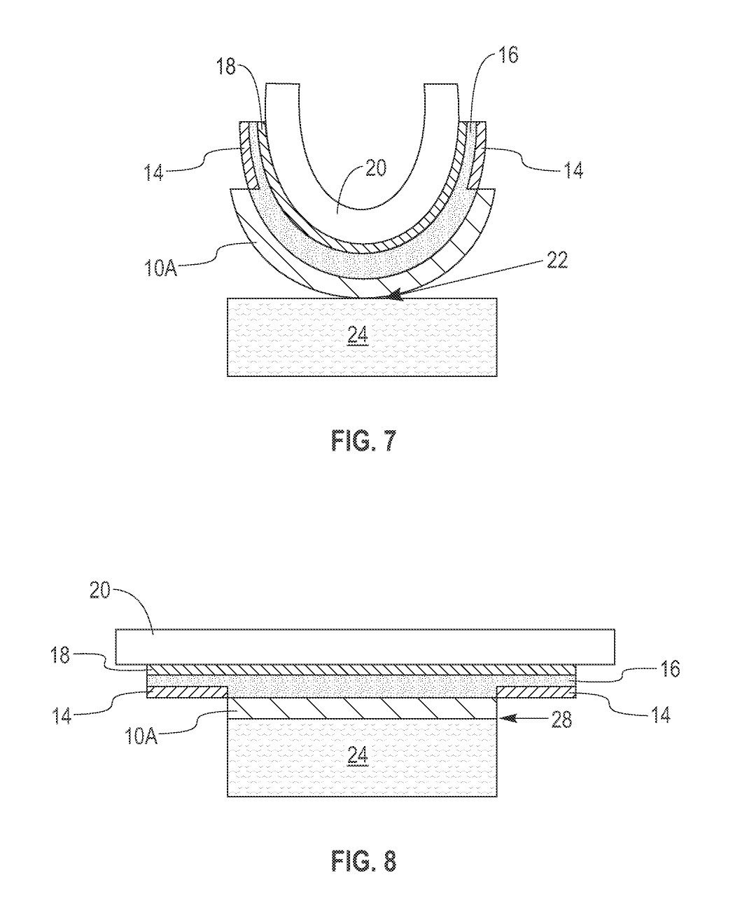

Referring now to FIG. 7, there is illustrated the exemplary structure of FIG. 6 after contacting an outermost bowed surface 22 of the spalled material portion 10A of the base substrate 10 to a substrate 24; due to the curved nature of the spalled material portion 10A, the entire surface of the spalled material portion 10A that is opposite the surface in which the stressor layer 18 is present does not contact the entire surface of the substrate 24. The bowed surface 22 of the spalled material portion 10A is located opposite a surface of the spalled material portion 10A in which the stressor layer 18 is present. In the embodiment illustrated in the present application, the outermost bowed surface 22 of the spalled material portion 10A of the base substrate 10 is located at a center point along a length of spalled material portion 10A. In other embodiments, the outermost bowed surface 22 of the spalled material portion 10A can fluctuate from about 0.1 nm to 10 nm from the center point along a length of the spalled material portion 10A. In this embodiment, the spalled material portion 10A may be referred to a first substrate having a radius of curvature, while substrate 24 may be referred to as a second substrate; the second substrate is flat relative to the first substrate.

The substrate 24 may be flexible, or non-flexible (i.e., rigid). By “flexible substrate”, it is meant a substrate that can be bended by hand or by applying a slight external force to the substrate. In some embodiments, the substrate 24 may be comprised of a semiconductor material. In other embodiments, the substrate 24 may be comprised of a dielectric material.

In one embodiment of the present application, the contacting of the outermost bowed surface 22 of the spalled material portion 10A to substrate 24 may be performed by hand. In another embodiment of the present application, the contacting of the outermost bowed surface 22 of the spalled material portion 10A to substrate 24 may be performed by a mechanical means such as, for example, a robot hand, or a vice. The contacting of the outermost bowed surface 22 of the spalled material portion 10A to substrate 24 may be performed at any temperature so long as the contacting temperature does not release curvature of the spalled material portion 10A. In one embodiment of the present application, the contacting of the outermost bowed surface 22 of the spalled material portion 10A to substrate 24 may be performed at nominal room temperature (i.e., 15° C.-40° C., i.e., 288K-313K).

Referring now to FIG. 8, there is illustrated the exemplary structure of FIG. 7 after performing the bonding process of the present application. Bonding provides a flat bonded structure (10A/24) that has a bubble free uniform bonding interface 28 between the spalled material portion 10A and substrate 24. By “flat” it is meant that the bonded structure has a zero radius of curvature. Thus, the entirety of a surface of the spalled material portion 10A is in direct physical contact with a surface of substrate 24.

The bonding process of the present application is performed at a temperature that removes the radius of curvature of spalled material portion 10A. That is, the radius of curvature of the spalled material portion 10A can be modulated by the temperature at which the bonding process of the present application is performed. Notably, the radius of curvature of the spalled material portion 10A is reduced and eventually flattens out by adjusting the temperature of the bonding process. When the radius of curvature is reduced and flattens out, the bonding area is extended to the entire surface of substrate 24. The temperature that is employed in the bonding process of the present application may be greater than or lesser than the temperature that is used to during spalling. In one embodiment of the present application, the temperature of the bonding process of the present application can be from 25° C. to 300° C. In another embodiment of the present application, the temperature of the bonding process of the present application can be from 0° C. to 600° C. In a further embodiment, bonding can be performed at a temperature from 1° C. to 1200° C.

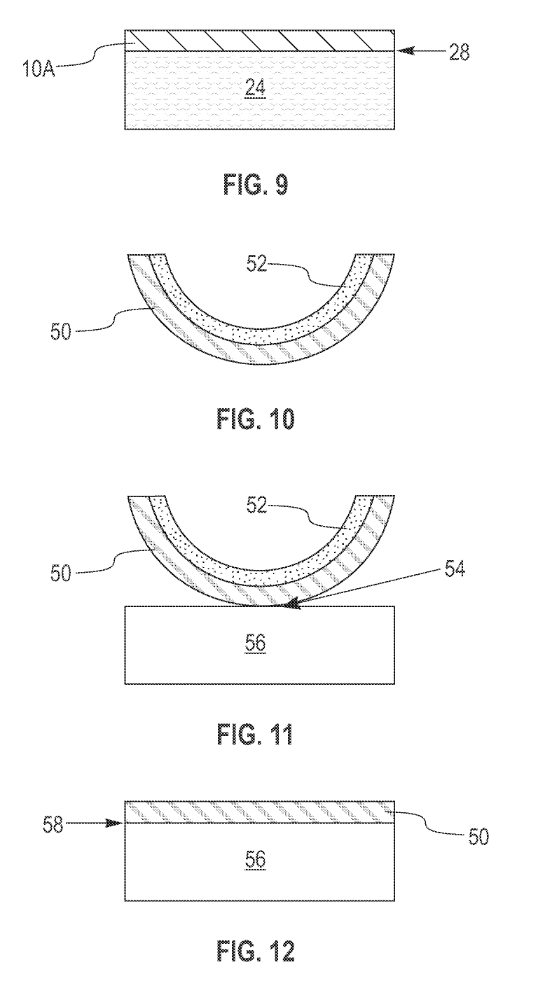

Referring now to FIG. 9, there is illustrated the exemplary structure of FIG. 8 after removing various material layers from the bonded structure 10A/24. In some embodiments of the present application, this step may be entirely omitted, and the resultant bonded structure 10A/24 may include any of the handle substrate 20, the stressor layer 18, the plating seed layer, the metal-containing adhesion layer 16, and the edge exclusion material 14.

The various materials (i.e., any of the handle substrate 20, the stressor layer 18, the plating seed layer, the metal-containing adhesion layer 16, and the edge exclusion material 14) can be removed utilizing conventional techniques well known to those skilled in the art. For example, and in one embodiment, aqua regia (HNO₃/HCl) can be used for removing the handle substrate 20, the stressor layer 18, the plating seed layer, and the metal-containing adhesion layer 16. In another example, UV or heat treatment is used to remove the handle substrate 20 followed by a chemical etch to remove the stressor layer 18, followed by a different chemical etch to remove the plating seed layer, and/or the metal-containing adhesion layer 16. The edge exclusion material 14 can be removed utilizing an organic solvent such, for example, as acetone.

The above description and FIGS. 1-9 illustrate an embodiment of the present application in which a spalled material portion 10A of a base substrate 10 is bonded to a substrate 24. In another embodiment, the method of the present application can be used to bond a non-spalled base substrate to another substrate. This particular embodiment of the present application, which is illustrated in FIGS. 10-12, will now be described in greater detail.

Referring first to FIG. 10, there is illustrated another exemplary structure including a base substrate 50 and a stressor layer 52 in accordance with another embodiment of the present application. The base substrate 50 that is employed in this embodiment of the present application may include one of the materials mentioned above for the base substrate 10 shown in FIG. 1 of the present application. The stressor layer 52 that is employed in this embodiment of the present application may include one of the materials mentioned above for stressor layer 18 shown in FIG. 4 of the present application. Stressor layer 52 can be formed utilizing one of the techniques mentioned above in forming stressor layer 18. Although not shown, an optional metal-containing adhesion layer and/or an optional plating seed layer (as described above) can be disposed between the base substrate 50 and the stressor layer 52. As shown, the stressor layer 52 induces a stress in the base substrate 50 providing a radius of curvature to the base substrate 50. The curvature of base substrate 50 is induced by the stress in the stress layer 52. The stress can come from either intrinsic stress or thermal expansion mismatch induced stress.

Referring now to FIG. 11, there is illustrated the exemplary structure of FIG. 10 after contacting an outermost bowed surface 54 of the base substrate 50 to a substrate 56. The bowed surface 54 is a surface that is opposite a surface of base substrate 50 that includes the stressor layer 52. The substrate 56 that is employed in this embodiment of the present application includes one of the materials mentioned above for substrate. Due to the curved nature of the base structure shown in FIG. 10, the entire surface of the base substrate 50 that is opposite the surface in which the stressor layer 52 is present does not contact the entire surface of the substrate 56. In the embodiment illustrated in the present application, the outermost bowed surface 54 of the base substrate 50 is located at a center point along a length of base substrate 50. In other embodiments, the outermost bowed surface 54 of the base substrate 50 can fluctuate from about 0.1 nm to 100 nm from the center point along a length of the base substrate 50.

The substrate 56 may be flexible, or non-flexible (i.e., rigid). In some embodiments, the substrate 56 may be comprised of a semiconductor material. In other embodiments, the substrate 56 may be comprised of a dielectric material. In this embodiment, the base substrate 50 may be referred to a first substrate having a radius of curvature, while substrate 56 may be referred to as a second substrate; the second substrate is flat relative to the first substrate.

In one embodiment of the present application, the contacting of the outermost bowed surface 54 of the base substrate 50 to substrate 56 may be performed by hand. In another embodiment of the contacting of the outermost bowed surface 54 of the base substrate 50 to substrate 56 may be performed by a mechanical means such as, for example, a robot hand, or a vice. The contacting of the outermost bowed surface 54 of the base substrate 50 to substrate 56 may be performed at any temperature so long as the contacting temperature does not release the stress applied by the stressor material 52 to the base substrate 50. In one embodiment of the present application, the contacting of the outermost bowed surface 54 of the base substrate 50 to substrate 56 may be performed at nominal room temperature (i.e., 15° C.-40° C., i.e., 288K-313K).

Referring now to FIG. 12, there is illustrated the exemplary structure of FIG. 11 after performing the bonding process and removing the stressor layer 52 from the bonded structure (50/56). Bonding provides a flat bonded structure (50/56) that has a bubble free uniform bonding interface 58 between the base substrate 50 and substrate 56. Thus, the entirety of a surface of the base substrate 50 is in physical contact with a surface of substrate 56.

The bonding process of the present application is performed at a temperature that removes the radius of curvature of base substrate 50. That is, the radius of curvature of the base substrate 50 can be modulated by the temperature at which the bonding process of the present application is performed. Notably, the radius of curvature of the base substrate 50 is reduced and eventually flattens out by adjusting the temperature of the bonding process. When the radius of curvature is reduced and flattens out, the bonding area is extended to the entire surface of substrate 56. The temperature that is employed in the bonding process of the present application may be greater than or lesser than the temperature that is used in inducing the stress into the base substrate 50. In one embodiment of the present application, the temperature of the bonding process of the present application can be from 25° C. to 300° C. In another embodiment of the present application, the temperature of the bonding process of the present application can be from 0° C. to 600° C. In a further embodiment, bonding can be performed at a temperature from 1° C. to 1200° C.

The stressor layer 52 can be removed utilizing techniques well known to those skilled in the art. For example, and in one embodiment, aqua regia (HNO₃/HCl) or another chemical etchant can be used for removing the stressor layer 52 from the bonded structure (50/56). In some embodiments, the stressor layer 52 can remain within the structure.

In either embodiment of the present application, the substrate 24/56 can be a permanent substrate or a temporary substrate. When substrate 24/56 is a temporary substrate, substrate 24/56 can be removed after processing the spalled material portion 10A or base substrate 50. The removal of substrate 24/56 can be performed utilizing techniques well known to those skilled in the art.

While the present application has been particularly shown and described with respect to various embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A method of bonding a first substrate to a second substrate, said method comprising:
providing a first substrate having a radius of curvature and containing a stressor layer;
contacting an outermost bowed surface of said first substrate to a portion of a surface of a second substrate; and
bonding said first substrate to an entirety of said surface of said second substrate, wherein said bonding is performed at a temperature that removes said radius of curvature of said first substrate.

2. The method of claim 1, wherein said first substrate comprises a spalled material portion of a base substrate.

3. The method of claim 2, wherein said spalled material portion of said base substrate is provided by a method that comprises:
forming said stressor layer above a surface of said base substrate; and
removing said material portion of said base substrate from said base substrate by performing a spalling process.

4. The method of claim 3, further comprising forming an edge exclusion material on said surface and at each vertical edge of said base substrate prior to forming said stressor layer.

5. The method of claim 4, wherein said edge exclusion material comprises a photoresist material, a polymer, a hydrocarbon material, an ink, a metal, or a paste.

6. The method of claim 3, further comprising forming a handle substrate on an exposed surface of said stressor layer prior to performing said spalling process.

7. The method of claim 6, wherein said spalling process further comprises pulling or peeling said handle substrate.

8. The method of claim 1, wherein said spalling process is performed at room temperature.

9. The method of claim 3, wherein said stressor layer comprises a metal, a polymer, a spalling inducing tape or any combination thereof.

10. The method of claim 3, wherein said stressor layer comprises Ni.

11. The method of claim 1, wherein said first substrate comprises a non-spalled base substrate.

12. The method of claim 11, wherein said stressor layer comprises a metal, a polymer, a spalling inducing tape or any combination thereof.

13. The method of claim 12, wherein said stressor layer comprises Ni.

14. The method of claim 1, further comprising removing at least said stressor layer from said first substrate after said bonding is performed.

15. The method of claim 1, wherein said bonding provides a bubble free uniform interface between said first substrate and said second substrate.

16. The method of claim 1, wherein said contacting is performed by hand.

17. The method of claim 1, wherein said contacting is performed by a mechanical means.

18. The method of claim 1, wherein said temperature of said bonding from 1° C. to 1200° C.

19. The method of claim 1, wherein said second substrate is a flexible substrate.

20. The method of claim 1, wherein said outermost bowed surface of said first substrate is located as a center point along a length of said first substrate.
